(19) United States
(12) Patent Application Publication
(10) Pub. No.: US 2007/0161203 A1
(43) Pub. Date: Jul. 12, 2007

(54) Method with high gapfill capability and resulting device structure

(75) Inventor: Ting Cheong Ang, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Shanghai (CN)

(21) Appl. No.: 11/321,408

(22) Filed: Dec. 28, 2005

(30) Foreign Application Priority Data
Dec. 5, 2005 (CN) 200510111129.0

(51) Int. Cl. H01L 21/76

(52) U.S. Cl. 438/400

(57) ABSTRACT

A method for filling a trench includes forming a first layer in a trench in order to partially fill the trench, removing at least a potion of the first layer from the trench; and forming a second layer on the first layer, wherein the forming a second layer is performed at a temperature of at least 700 degrees C. and at a gas flow ratio of at least 1.6, the gas flow ratio being equal to a first gas flow rate for a first gas to a second gas flow rate for a second gas. In a specific embodiment, the method includes removing a contaminant from the first layer by reacting with the contaminant present in the first layer at the temperature and with the gas flow ratio. In a specific embodiment, the removing at least a portion of the first layer includes etching the portion of the first layer.

### CROSS-REFERENCES TO RELATED APPLICATIONS

This application claims priority to Chinese Patent Application No. 200510111129.0, filed Dec. 5, 2005, commonly assigned and of which is incorporated by reference herein for all purposes.

### BACKGROUND OF THE INVENTION

The present invention is directed to integrated circuits and their processing for the manufacture of semiconductor devices. More particularly, the invention provides a CVD deposition method with high gapfill capability and a resulting device structure. Merely by way of example, the invention has been applied to making shallow trench isolation (STI) regions. But it can be recognized that the invention has a much broader range of applicability.

Integrated circuits or “ICs” have evolved from a handful of interconnected devices fabricated on a single chip of silicon to millions of devices. Current ICs provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of ICs. Semiconductor devices are now being fabricated with features less than a quarter of a micron across.

Increasing circuit density has not only improved the complexity and performance of ICs but has also provided lower cost parts to the consumer. An IC fabrication facility can cost hundreds of millions, or even billions, of dollars. Each fabrication facility will have a certain throughput of wafers, and each wafer will have a certain number of ICs on it. Therefore, by making the individual devices of an IC smaller, more devices may be fabricated on each wafer, thus increasing the output of the fabrication facility. Making devices smaller is very challenging, as each process used in IC fabrication has a limit. That is to say, a given process typically only works down to a certain feature size, and then either the process or the device layout needs to be changed. Additionally, as devices require faster and faster designs, process limitations exist with conventional processes and materials.

One such example of a process limitation deals with the difficulty of filling a trench that has a high aspect ratio, meaning that the ratio of the depth of the trench to the trench opening is large. A high aspect ratio can cause problems during the trench fill process in that the deposited material is not uniformly distributed over the surface area of the trench, leading to overhang of the deposited material at the trench corner and voids at the center of the trench. This can lead to problems with device performance and electrical reliability.

From the above, it is seen that an improved technique for processing semiconductor devices is desired.

### BRIEF SUMMARY OF THE INVENTION

The present invention is directed to integrated circuits and their processing for the manufacture of semiconductor devices. More particularly, the invention provides a CVD deposition method with high gapfill capability and a resulting device structure. Merely by way of example, the invention has been applied to making shallow trench isolation (STI) regions. But it can be recognized that the invention has a much broader range of applicability.

In a specific embodiment, a method for filling a trench using an STI gapfill process is disclosed. The method includes depositing a first dielectric layer within the trench. The first dielectric layer lines a bottom surface and sidewalls of the trench. Additionally, the method includes removing a portion of the first dielectric layer from the sidewalls and top corners of the trench to decrease an aspect ratio of the trench, and depositing a second dielectric layer within the trench to fill the trench. The depositing a second dielectric layer is performed at a first temperature at or above 700 degrees C. and a first gas flow ratio of O₂ to SiH₄ of at least 1.6.

In another specific embodiment, a method of filling a trench on a semiconductor substrate is provided. The method includes forming a first layer in a trench in order to partially fill the trench, removing at least a potion of the first layer from the trench, and forming a second layer on the first layer. For example, the forming a second layer is performed at a temperature of at least 700 degrees C. and at a gas flow ratio of at least 1.6, the gas flow ratio being equal to a first gas flow rate for a first gas to a second gas flow rate for a second gas. In a specific embodiment, the method comprises removing a contaminant from the first layer by reacting with the contaminant present in the first layer at the temperature and with the gas flow ratio. In a specific embodiment, the removing at least a portion of the first layer comprises etching the portion of the first layer.

In yet another specific embodiment, a structure formed on a semiconductor substrate is provided. The structure comprises a trench located on or extending into the semiconductor substrate, mesa regions adjacent to the trench, a dielectric layer formed using a deposition-etch-deposition process filling the trench and covering the mesa regions, wherein the dielectric layer is associated with a fluorine content of less than 10 parts per million.

Many benefits are achieved by way of the present invention over conventional techniques. For example, the present technique provides an easy to use process that relies upon conventional technology. In some embodiments, an effective gapfill process is provided which improves the device reliability and performance of a semiconductor circuit. Additionally, the method provides a process that is compatible with conventional process technology without substantial modifications to conventional equipment and processes. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIGS. 1A and 1B are scanning electron microscope (SEM) images of across-section of a silicon substrate showing voiding in a simplified conventional trench filling method;

FIG. 2 is a simplified conventional trench filling method;

FIGS. 3A-3C are exemplary cross-sectional views of a semiconductor substrate during a conventional trench filling method;

FIGS. 4A and 4B are SEM images of a cross-section of a silicon substrate showing abnormal layers on a trench sidewall formed during a conventional trench filling method;

FIG. 5 is a simplified trench filling method according to an embodiment of the present invention;

FIGS. 6A-6C are exemplary cross-sectional views of a semiconductor substrate showing a trench filling method that prevent abnormal layers from forming on the trench sidewall;

FIG. 7 is a SEM image of a cross-section of a silicon substrate showing a trench filling process that does not exhibit abnormal layers on the trench sidewall;

FIG. 8 is a simplified trench filling method according to another embodiment of the present invention;

FIG. 9 is a simplified trench filling method according to another embodiment of the present invention;

### DETAILED DESCRIPTION OF THE INVENTION

The present invention is directed to integrated circuits and their processing for the manufacture of semiconductor devices. More particularly, the invention provides an CVD deposition method with high gapfill gapfill capability and a resulting device structure. Merely by way of example, the invention has been applied to making shallow trench isolation (STI) regions. But it can be recognized that the invention has a much broader range of applicability.

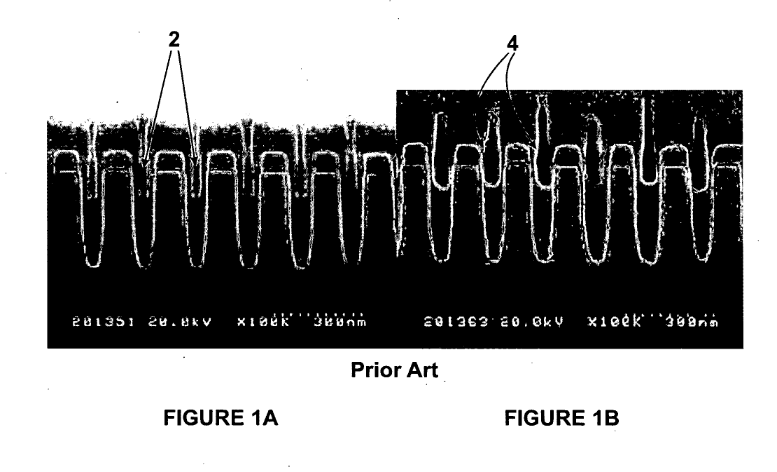

FIGS. 1A and 1B are scanning electron microscope (SEM) images of a cross-section of a silicon substrate showing voiding in a conventional trench filling process. A deposition process is used to fill the high aspect ratio trenches formed within the substrate. For example, a high aspect ratio trench is a trench where the ratio of the trench depth to the trench width is greater than 5:1. A trench with exemplary dimensions of a trench opening of 12 μm and a depth of 5000 Å can incur a number of problems when performing a deposition process. One major problem that can occur is that overhang of the deposited material on the top corners of the trench can cause voids to form in the deposited material. For example, the inventor has discovered that this occurs because a larger amount of the deposited material collects on the corners of the trench instead of being evenly distributed throughout the trench. As material collects on the corners of the trench, it encroaches into the trench opening and causes more and more material to be deposited on the trench corners. More specifically, the trench aperture may have a reentrant angle whereby the upper width of the aperture is smaller than the bottom width of the trench. This causes voids 2 and 4 to form within the central portion of the trench, which can result in increased resistance in the deposited film, reliability problems of integrated circuits being formed by the structure of FIGS. 1A and 1B, and ultimately device failure that results in lowered yield rates of the process by which the integrated circuits are manufactured.

One exemplary solution to the problem of voiding caused by overhang is to employ a deposition-etch-deposition process sequence instead of the single deposition process used to fill the trenches in FIGS. 1A and 1B.

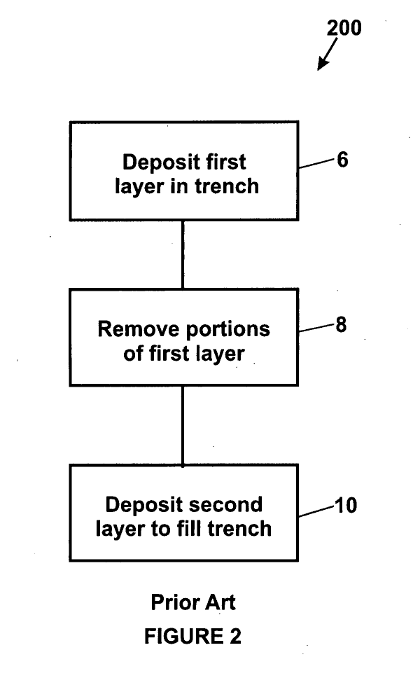

FIG. 2 is a simplified conventional trench filling method. The method 200 includes a process 6 for depositing a first layer in trench, a process 8 for removing a portion of the first layer, and a process 10 for depositing a second layer to fill the trench.

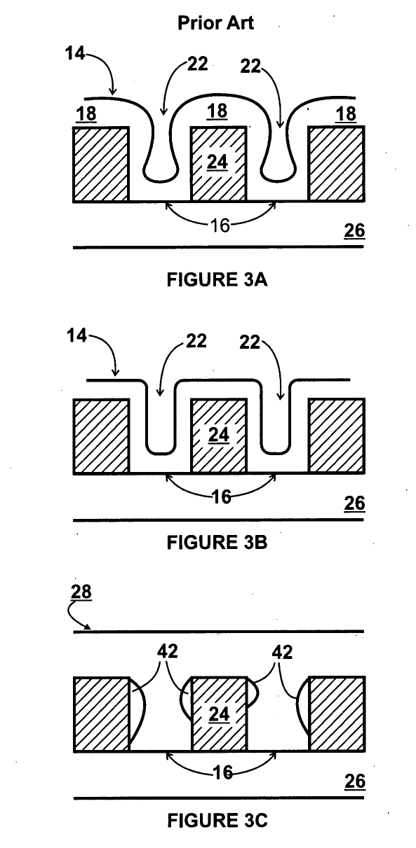

An exemplary process flow showing such a trench filling method is shown in FIG. 2, and may be viewed in conjunction with exemplary cross-sectional views of a semiconductor substrate during a conventional trench filling method as shown in FIG. 3A-3C. In process 6, a first layer 14 is deposited in trenches 16 formed on top of substrate 26. The dielectric layer covers regions 24 which are adjacent to the trenches being filled. Regions 24 may comprise metal layers deposited on top of the substrate, but may also comprise nitride and pad oxide layers formed on top of the metal layers which are used during subsequent removal processes. The deposition process may optionally be an HDP-CVD process which deposits a dielectric layer into the trench to be filled, but may comprise other processes such as PE-CVD, LP-CVD, MOCVD, PVD processes among others. The deposition process is typically performed at a temperature of 550 degrees Celsius or below, with a gas flow ratio of a first gas to a second gas of 1.0-1.2. Higher temperatures are not employed because of the additional expenditure required for the thermal budget of the process. Higher temperatures can also result in greater stress of the silicon substrate being deposited on. The gas flow ratio of the first gas to the second gas is of importance because the amount of deposition gas being flowed during the deposition process affects the deposition rate of the material being deposited. In one embodiment of the invention, the first gas and the second gas being flowed are O₂ and SiH₄, respectively. However, the high aspect ratio of the trench prevents the trench from be fully filled within one deposition process. Thus, process 6 deposits a layer that covers the trench sidewalls and bottom, but does not fully fill trenches 16. However, a ‘breadloaf’ or cusp section 18 is formed on top of the conductive regions 24 which effectively reduces the width of the adjacent trench apertures 22. The breadloaf section is referred to as such because the deposition process results in an overhang structure that looks similar to a loaf of bread, being wider at its top than at its base. This makes filling of the gap with subsequently deposited dielectric material difficult because the trench aspect ratio is effectively increased by reducing the width of the trench aperture 22 and this creates a reentrant angle for trench aperture 22 even if one did not previously exist.

To remedy this problem, an etch process 8 is used to remove portions of the first deposited layer on the sidewalls of the trench. A variety of different etch processes can be employed, such as, but not limited to, sputter etching, reactive ion etching, and others. Trench apertures 22 are widened to a degree to remove overhang from the top corners of the trench and effectively increase the aspect ratio of the area being deposited to. A portion of the deposited layer 14 above the conductive regions 24 is also removed during the etch process. An effect of the removal of the breadloaf edges from the trench sidewall is that the etched material is effectively redeposited near the trench bottom, resulting in potentially shorter deposition time for a subsequent deposition process. In an exemplary embodiment of the invention, an anisotropic fluorine etch process is used to remove portions of first deposited layer 14.

Following the etch process, a second deposition process 10 is used to complete the filling of the trenches 16 between conductive regions 24. The trenches are filled to a height above the conductive regions, and a chemical-mechanical polishing process can be employed subsequently to reduce the deposited layer 28 to a desired level.

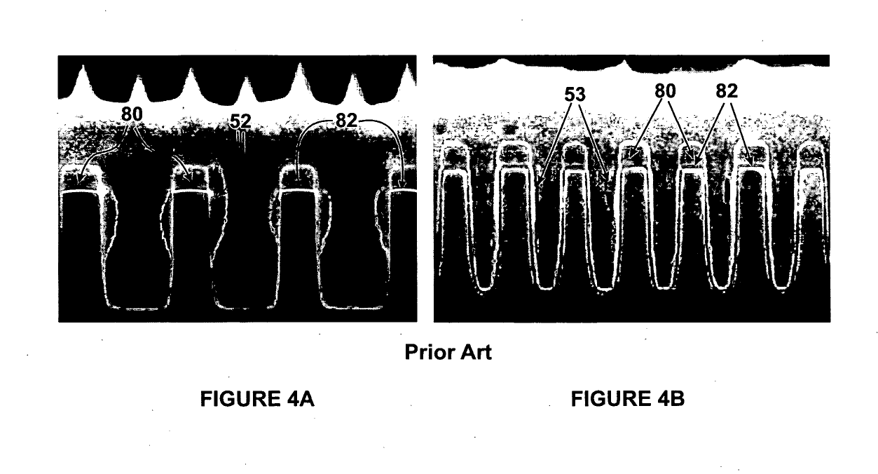

FIGS. 4A and 4B are SEM images of a cross-section of a silicon substrate showing abnormal layers on a trench sidewall formed during a conventional trench filling method. Abnormal layers 52, 53 are formed on the trench sidewalls, further causing oxide loss on the sidewall after a CMP process is used to planarize the deposited layer. The abnormal layers may also have effects similar to voiding after a buffered oxide etch is used to remove nitride 80 and pad oxide 82 layers, which results in a faster etch rate than is desired and can result in overetching. [please confirm] Problems in transistor performance can arise due to the leakage currents that can arise due to the formation of these abnormal layers. For this reason, removal of the abnormal layers occurring at areas where redeposition occurs is desired.

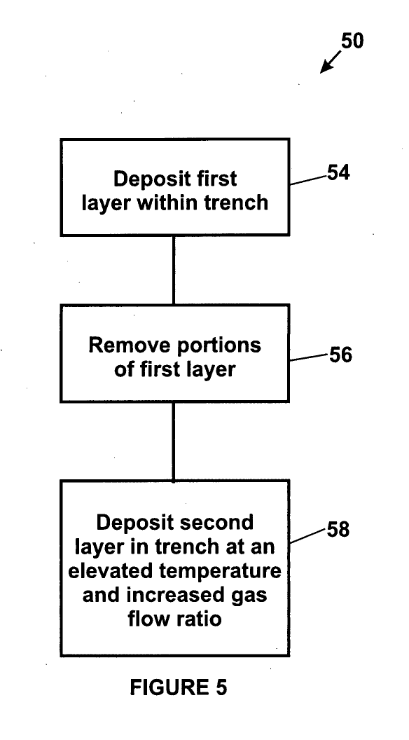

FIG. 5 is a simplified trench filling method according to an embodiment of the present invention. This diagram is merely an example, which should not unduly limit the scope of the claims. One of ordinary skill in the art would recognize many variations, alternatives, and modifications. The method 50 includes a process 54 for depositing a first layer within a trench, a process 56 for removing a portion of the first layer, and a process 58 for depositing a second layer at an elevated temperature and high gas ratio. Further details of these processes are found throughout the present specification and more particularly below.

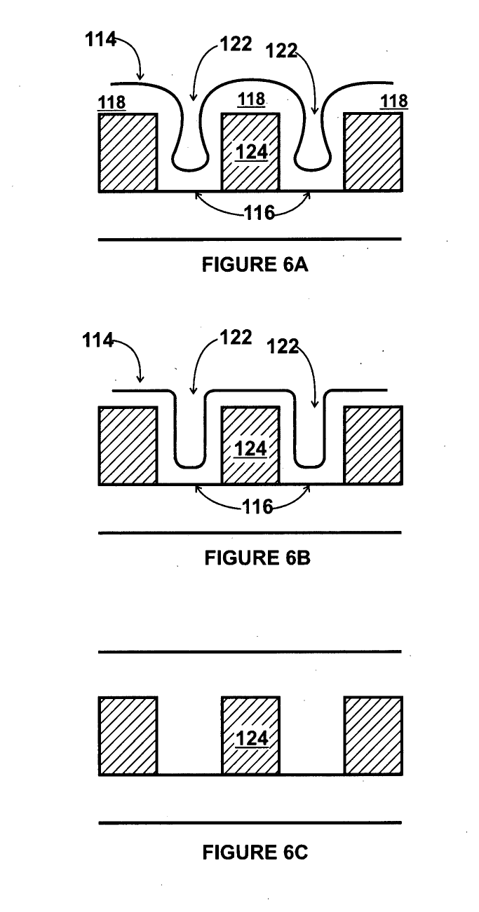

For example, FIG. 5 describes an exemplary process flow showing a trench fill process that prevents abnormal layers from forming on the trench sidewall. FIGS. 6A-6C are exemplary cross-sectional views of a semiconductor substrate showing a trench filling method that prevents abnormal layers from forming on the trench sidewall. FIGS. 6A-6C are merely examples, which should not unduly limit the scope of the claims. One of ordinary skill in the art would recognize many variations, alternatives, and modifications.

In process 54, a first layer is deposited within a trench. For example, a first layer 114 is deposited within the trench covering the trench 116 sidewalls and bottom and also covering regions 124. Regions 124 may comprise metal layers deposited on the substrate and/or nitride and pad oxide layers deposited on the metal layers used in the removal processes of the deposited oxide layers. In a specific embodiment, regions 124 may be formed with a conductive material. For example, a ‘breadloaf’ or cusp section 118 is formed overlying of the regions 124 which effectively reduces the width of the adjacent trench apertures 122. The breadloaf section is referred to as such because the deposition process results in an overhang structure that looks similar to a loaf of bread, being wider at the top than at the base.

In process 56, a portion of the first layer is removed. Removal process 56 is used within the gapfill process to remove portions of the first deposited layer on the sidewalls and top corners of the trench. This widens trench apertures 122 to a sufficient degree to remove overhang from the top corners of the trench and decreases the aspect ratio of the area to be deposited into in the subsequent process. A portion of deposited layer 114 above the conductive regions 124 is also removed during the etch process. An effect of the removal of the breadloaf edges from the trench sidewall is that the etched material is effectively redeposited near the trench bottom, resulting in potentially shorter deposition time for an upcoming deposition process. In an exemplary embodiment of the invention, an anisotropic fluorine etch process is used to remove portions of first deposited layer 114.

In process 56, a second layer is deposited at an elevated temperature and a high gas ratio. For example, following removal process 56, a second deposition process is used to fill trench apertures 122 with a second layer of deposited material in process 58. This layer of deposited material covers both regions 124 and first deposited layer 114 that has been etched to allow for improved trench deposition coverage. The deposited layer extends to a height above regions 124 to be removed in future planarization processes. The second deposited layer may include material that is the same or different from the first. For example, the combination of deposited layers may provide for superior gapfill or isolation properties.

According to an embodiment of the present invention, deposition process 58 is performed at an elevated temperature of at least 700 degrees C. and with a gas flow ratio of the first gas to the second gas of 1.6 or higher. In one specific embodiment of the invention, the first gas that is used during deposition is O₂, the second gas used during deposition is SiH₄, and fluorine is used as an echant during removal process 56. The inventors have discovered that following the second deposition process at an elevated process temperature and with a increased gas flow rate of the first gas to the second gas, formation of abnormal layers 42 in the regions of redeposition is prevented or reduced. The levels of fluorine present within the deposited layers after the second deposition process has been completed in process 58 is less than 10 parts per million (ppm), a level commensurate with the use of non-fluorine etchants.

In a specific embodiment of the invention, a structure is formed on a semiconductor substrate which comprises a trench located on or extending into the semiconductor substrate, mesa regions adjacent to the trench, a dielectric layer formed using a deposition-etch-deposition process filling the trench and covering the mesa regions, wherein the dielectric layer has a fluorine content of less than 10 parts per million. In a specific embodiment, the structure may further comprise an oxide layer disposed on the mesa regions, and a nitride layer disposed over the oxide layer.

It has been discovered that increasing the gas flow ratio of the first gas to the second gas during deposition, in conjunction with increasing the process temperature during deposition, leads to normal deposition of the redeposited layer without any formation of abnormal layers.

For example, one potential explanation provided by the inventor is that by increasing the amount of the first gas being flowed, it allows the first gas to decompose the bonds of the second gas at an accelerated rate. This allows the molecules within the second gas to react and bond with the contaminants present in the deposited layer in a gas phase to remove them from the deposited layer. A specific example can be illustrated when the gases being flowed are O₂ and SiH₄, and the contaminant present is fluorine remaining from the etch process 56. The greater amount of O₂ being flowed assists in the disassociation of SiH₄ into silicon and hydrogen and allows the silicon molecules to react with the fluorine present on the trench sidewalls to form tetrafluorosilane, or SiF₄, which normally exists in a gaseous phase. SiF₄ can then be removed from the processing environment by a vacuum or pumping mechanism without any adverse effect to the processing of the substrate.

While the removal of the contaminants has been described in the context of a deposition-etch-deposition process, it is not meant as being limited to that specific instance. For example, an elevated temperature and increased gas flow ratio of a first gas to a second gas during deposition could be used to remove contaminants introduced to the substrate in another manner other than an etch process. If fluorine is taken as an exemplary contaminant, it can be introduced into the substrate processing environment or the substrate itself due to a prior ashing process, use as a cleaning agent to clean surfaces within the substrate processing environment, or use within in microlithography and patterning of the substrate. According to certain embodiments of the present invention, the process being conducted can remove contaminants introduced by a variety of methods and is not limited to those introduced during the etch process.

Method 50 may be performed in-situ within the same processing environment, or may be performed ex-situ between in different processing environments. The choice between the processes of the method 50 are performed as an in-situ or ex-situ process is dependent on the process equipment implementation at the semiconductor manufacturing site and the integration flow chosen by the manufacturer.

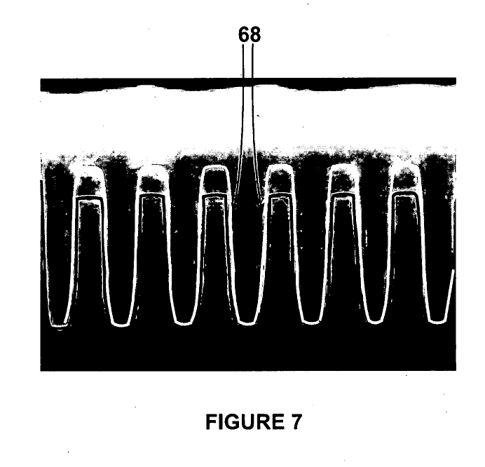

FIG. 7 is a SEM image of a cross-section of a silicon substrate showing a trench filling process that does not exhibit abnormal layers on the trench sidewall. This diagram is merely an example, which should not unduly limit the scope of the claims. One of ordinary skill in the art would recognize many variations, alternatives, and modifications. Trench sidewalls 68 do not show abnormal formation of layers due to contaminants introduced during the etch process as the contaminants have been removed.

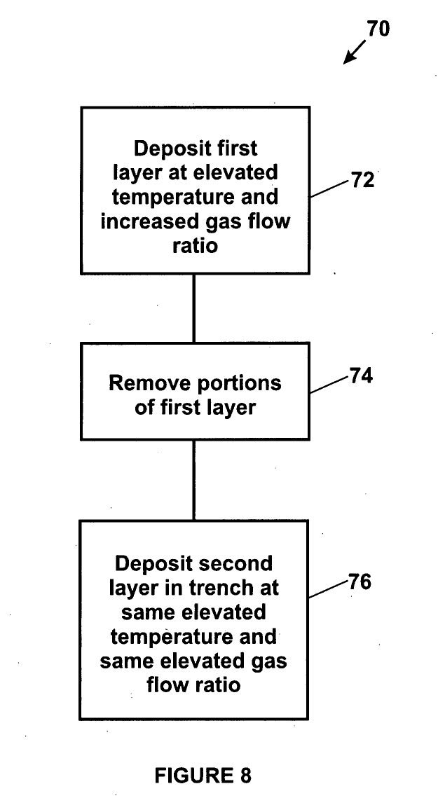

FIG. 8 is a simplified trench filling method according to another embodiment of the present invention. This diagram is merely an example, which should not unduly limit the scope of the claims. One of ordinary skill in the art would recognize many variations, alternatives, and modifications. The method 70 includes a process 72 for depositing a first layer within a trench at an elevated temperature and increased gas flow ratio, a process 74 for removing a portion of the first layer, and a process 76 for depositing a second layer at the same elevated temperature and same elevated gas flow ratio as in process 72. Further details of these processes are found throughout the present specification and more particularly below.

In a specific embodiment, deposition process 72 is performed at an elevated temperature of above 700 degrees C. and with a gas flow ratio of a first gas to a second gas greater than 1.6. Removal process 74 is used to remove overhang of excess deposited material from the trench corners and sidewalls and widen the trench aperture which effectively reduces the aspect ratio of area to be deposited to by second deposition process 76. Second deposition process 76 is performed at the same elevated temperature as process 72 and with the same gas flow ratio of the first gas to the second gas greater than 1.6 and serves to complete the filling of the gap flow layer. One advantage towards performing both deposition processes at the same temperature is that it allows for simplification in the complexity of the process recipes utilized during the deposition process. This adds to the suitability of conducting the deposition-etch-deposition process in-situ in a single processing environment.

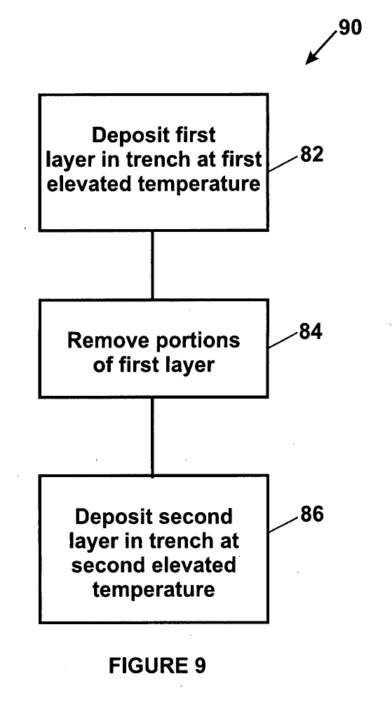

FIG. 9 is a simplified trench filling method according to another embodiment of the present invention. The method 90 includes a process 82 for depositing a first layer within a trench at a first temperature, a process 84 for removing a portion of the first layer, and a process 86 for depositing a second layer at a temperature different from the first temperature. This diagram is merely an example, which should not unduly limit the scope of the claims. One of ordinary skill in the art would recognize many variations, alternatives, and modifications.

In a specific embodiment, deposition process 82 is performed at a first elevated temperature of above 700 degrees C. and with a gas flow ratio of a first gas to a second gas greater than 1.6. Removal process 84 is used to remove overhang of excess deposited material from the trench corners and widen the trench aperture which effectively reduces the aspect ratio of area to be deposited to by second deposition process 86. Second deposition process 86 is performed at a second elevated temperature different from the first and with a gas flow ratio of the first gas to the second gas greater than 1.6 and serves to complete the filling of the gap flow layer. The second elevated temperature is also greater than 700 degrees C. One advantage towards using different elevated temperatures within the deposition processes is that flexibility is imparted to the manufacturer in terms of the thermal budget and energy consumed during the deposition processes.

It is also understood that the examples and embodiments described herein are for illustrative purposes only and that various modifications or changes in light thereof will be suggested to persons skilled in the art and are to be included within the spirit and purview of this application and scope of the appended claims.

1. A method for filling a trench, the method comprising:
forming a first layer to partially fill a trench at a first temperature and a first gas flow ratio, the gas flow ratio being equal to a first gas flow rate for a first gas to a second gas flow rate for a second gas;
removing at least a potion portion of the first layer from the trench, the remaining portion of the first layer including a first amount of contaminant; and
forming a second layer on the first layer;
wherein the forming a second layer is performed at a second temperature of at least 700 degrees C. and at a second gas flow ratio of at least 1.6, the second temperature and the second gas flow ratio during the forming the second layer causing a reduction of the first amount of contaminant to a second amount of contaminant, the second amount being substantially smaller than the first.

2. The method of claim 1 wherein the forming a second layer comprises removing the contaminant from the first layer by reacting the contaminant with an element dissociated from the second gas induced by the first gas at the second temperature and the second gas flow ratio.

3. The method of claim 1 wherein the first gas is O₂.

4. The method of claim 1 wherein the second gas is SiH₄.

5. The method of claim 1 wherein the removing at least a portion of the first layer comprises etching the portion of the first layer.

6. The method of claim 4 wherein the forming a second layer is performed by a HDP-CVD process.

7. The method of claim 1 wherein the forming a second layer is performed with a shallow trench isolation (STI) gapfill process.

8. The method of claim 1 wherein the first temperature is about 550 degrees C. or higher.

9. The method of claim 1 wherein the first temperature is at least 700 degrees C.

10. The method of claim 1 wherein the contaminant is fluorine element.

11. The method of claim 10 wherein after the forming the a second layer the second amount of fluorine contaminant present in the first layer and the second layer is equal to or less than 10 parts per million.

12. A method for filling a trench using an STI gapfill process, the method comprising:
depositing a first dielectric layer within the trench at a first temperature and a first gas flow ratio of O₂ to SiH₄, the first dielectric layer lining a bottom surface and sidewalls of the trench;
removing a portion of the first dielectric layer from the sidewalls and top corners of the trench to decrease an aspect ratio of the trench, the remaining portion of the first dielectric layer including a first amount of fluorine contaminant on the sidewalls of the trench; and
depositing a second dielectric layer within the trench to fill the trench,
wherein the depositing a second dielectric layer is performed at a second temperature at or above 700 degrees C. and a second gas flow ratio of O₂ to SiH₄ of at least 1.6, the second temperature and the second gas flow ratio during the depositing the second dielectric layer causing a reduction of the first amount of fluorine contaminant to a second amount of fluorine contaminant, the second amount being substantially smaller than the first amount.

13. The method of claim 12 wherein the removing a portion of the first dielectric layer is performed using an anisotropic etch process.

14. The method of claim 13 wherein the anisotropic etch process uses fluorine as an etchant.

15. The method of claim 14 wherein the second amount of fluorine contaminant present in the first dielectric layer and the second dielectric layer after the depositing a second dielectric layer is equal to or less than 10 parts per million.

16. The method of claim 12 wherein the first temperature is the same as the second temperature and the first gas flow ratio is the same as the second gas flow ratio.

17. The method of claim 12 wherein the first temperature is different from the second temperature.

18. The method of claim 12 wherein at least one of the depositing a first dielectric layer and the depositing a second dielectric layer is performed using a HDP-CVD process.

19. The method of claim 12 wherein the first and second dielectric layers comprise the same material.

20. The method of claim 12 wherein the first and second dielectric layers comprise different materials.

21. A structure formed on a semiconductor substrate comprising:
a trench located on or extending into the semiconductor substrate;
mesa regions adjacent to the trench;
a dielectric layer formed using a deposition-etch-deposition process filling the trench and covering the mesa regions;
wherein the dielectric layer is associated with a fluorine content of less than 10 parts per million.

22. The structure of claim 21 further comprising:
an oxide layer disposed on the mesa regions; and
a nitride layer disposed over the oxide layer.

23. The structure of claim 21 wherein the dielectric layer comprises a first dielectric sub-layer and a second dielectric sub-layer.
